(19) United States
(12) Patent Application Publication
(10) Pub. No.: US 2007/0152023 A1
(43) Pub. Date: Jul. 5, 2007

(54) Solder deposit method on electronic packages for post-connection process

(75) Inventors: Kenneth J. Huth, Whitsett, NC (US); Lawrence C. Monterulo, Yonkers, NY (US); John C. Sugrue, Stratford, CT (US)

Correspondence Address: CHARMASSON, BUCHACA & LEACH, LLP, 1545 HOTEL CIRCLE SOUTH, SUITE 150, SAN DIEGO, CA, 92108-3426, US

(73) Assignee: SEMX CORPORATION

(21) Appl. No.: 11/323,444

(22) Filed: Dec. 30, 2005

(51) Int. Cl. B23K 31/02; B21D 39/00; H01L 29/768

(52) U.S. Cl. 228/174; 228/180.1; 257/244

(57) ABSTRACT

A method for accurately depositing a continuous and homogeneous line of a minute, metered volume of solder to a delineated area of an electronic component comprises positioning over said area a template made of high temperature withstanding material such as high density graphite and having a series of spaced-apart bores joined at their base by a groove defining said line. Particles of solder having a cumulative size corresponding to said volume are inserted into the bores. The component and template assembly is then subjected to solder-melting temperature under a control atmosphere, causing the solder to flow and evenly deposit on the targeted area.

### FIELD OF THE INVENTION

This invention relates to microelectronic assemblies and packaging, and more particularly to the deposition of soldered strips on a lead frame or package lid for later reflow and connection.

### BACKGROUND

The extensive miniaturization of electronic circuits and their packaging requires the accurate deposition of minute, accurate quantity dabs or lines of solder over delineated areas of a component surface for future connecting of leads, lids and other parts by reflow.

The solder must be applied in controlled quantity and precisely on target in order to avoid bridging with other soldered points or circuit parts.

In the prior art, stamped soldered preforms are tack-welded to the electronic assembly or package in order to hold the solder in place for later remelting.

This invention results from attempts to devise a more precise method for depositing minute, accurate amounts of solder in precise locations without creating any smudges, burrs, voids or excess solder.

### SUMMARY

The instant embodiments provide a method for more accurately depositing a spot or line of solder on a narrowly limited area on the face of an electronic component that will be subject to a later reflow of the solder in order to establish a connection with a lead, package lid or other parts. The volume of required solder which is determined as a product of the superficies of the target area to be covered times the desired height of the solder patch or strip, is shaped into one or more particles of defined volume such as spheres. A guide or template made of a slab of material having a substantially higher melting point than the solder has a bottom surface that conforms intimately with the surface of the zone on an electronic component which includes the area upon which the solder is to be deposited. A cavity, cut into the bottom surface of the template, is shaped and dimensioned to congruently match the soldered area when the template rests upon the component. The depth of the cavity is at least equal to the desired height of the soldered deposit. Channels are bored from upper openings in the top surface of the template through lower openings positioned at regularly spaced-apart locations in the cavity. The particles of solder are inserted in the channels and the component and template assembly is subjected to a temperature at least as high as the melting temperature of the solder under a controlled atmosphere in an oven. As the particles are melted, the solder flows toward the targeted area on the face on the component, being restricted by the walls of the cavity to the precisely delineated area. The cumulative volume of the particles is determined by the total volume of solder to be deposited.

The above-described template and soldering method are particularly adapted for depositing either a spot or a line of solder on a lead frame for future attachment to the electronic package, or to apply a narrow line of solder on the marginal peripheral zone of an electronic package lid.

Some embodiments provide a method for accurately depositing a volume of solder of a given melting point to a given height on a delineated area of given superficies on the face of an electronic component, said method comprising the steps of: providing a slab of material having a bottom surface shaped and dimensioned for intimate contact with a zone of said face including said area, and a melting temperature substantially higher than said melting point; drilling through said slab at least one bore substantially perpendicular to said bottom surface and having a lower opening in said bottom surface falling within said area when said bottom surface is in contact with said zone; carving into said bottom surface and around said bottom opening, a cavity at least as deep as said height and shaped to be congruent with said delineated area; intimately contacting said face with said slab's bottom surface; inserting into said bore, a particle of said solder, said particle having a volume substantially equal to a product of said superficies times said height; and exposing said component and slab to a temperature at least equal to said melting point; whereby said particle of solder melts, flows and deposits accurately over said delineated area.

In some embodiments said delineated area is elongated about an axis; said step of drilling comprises drilling a plurality of said bores leading to spaced-apart openings along a line parallel to said axis within said cavity; and said step of inserting comprises inserting at least one of said particles in each of said bores, said particles having a cumulative volume equal to said product. In some embodiments said material comprises high density graphite. In some embodiments said solder comprise a gold alloy. In some embodiments said alloy is Au/Sn. In some embodiments said delineated area comprises an electronic package lead attachment area on a lead frame. In some embodiments said delineated area comprises a marginal, peripheral area on an electronic package lid.

Some embodiments provide a device for accurately depositing a volume of solder to a given height on a limited area on the face of an electronic component which comprises: a slab of material having a top surface, and a bottom surface shaped and dimensioned for conformingly resting upon a zone of said face including said area; said slab having at least one bore having a upper opening in said top surface and a lower opening in said bottom surface, said lower opening being positioned above said area when said bottom surface rests upon said zone; and said slab further having a cavity in said bottom surface and around said bottom opening, said cavity having a depth greater than said height, and being shaped to congruently fit over said limited area. In some embodiments the device further comprise a plurality of said bores having lower openings positioned at regularly spaced-apart locations along a line. In some embodiments said limited area comprises at least one lead connection spot on an electronic package lead frame. In some embodiments said limited area comprises a marginal, peripheral area on an electronic package lid. In some embodiments the device further comprises a small volume of solder inserted in each of said bores. In some embodiments said volume is obtained by dividing the amount of solder to be deposited by the number of bores. In some embodiments each of said volume consists of a particle of solder. In some embodiments said particle of solder has a shape selected from the group consisting of a sphere, a cylinder, and a quadranglarly sided shape.

### BRIEF DESCRIPTION OF THE DRAWING

FIG. 1 is a bottom plan view of a template according to the invention;

FIG. 2 is a cross-sectional view taken along line 2-2 of FIG. 1;

FIG. 3 is a cross-sectional view taken along line 3-3 of FIG. 1;

FIG. 4 is a top plan view of the template applied to a lead frame;

FIG. 5 is a bottom plan view of a template for an electronic package lid; and

FIG. 6 is a cross-sectional view of a package lid, template and framing fixture assembly.

### DESCRIPTION OF THE INSTANT EMBODIMENTS

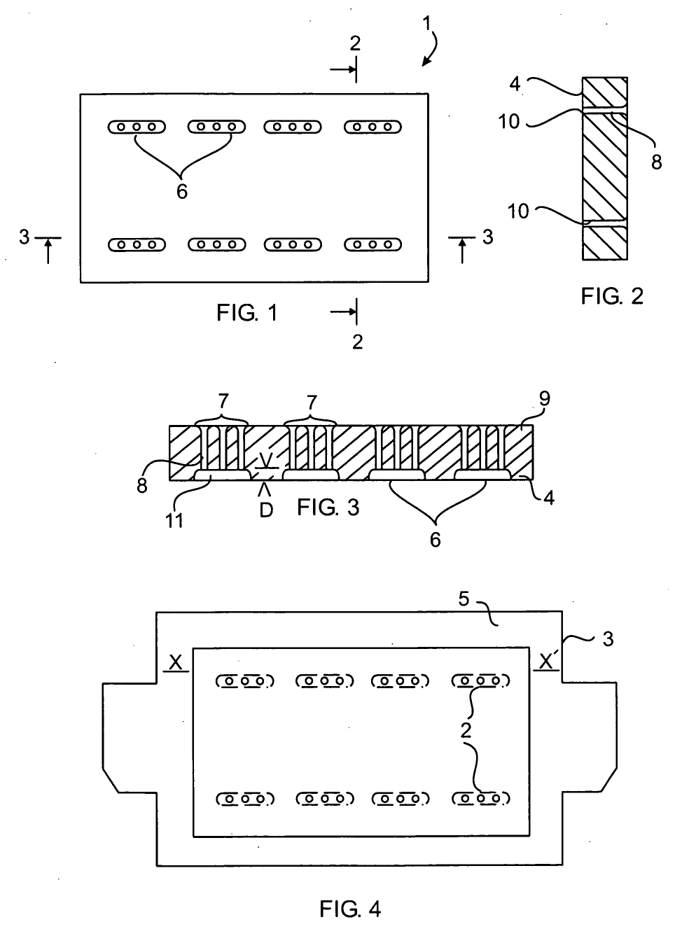

Referring now to the drawing, there is shown in FIGS. 1-4 a soldering guide or template 1 particularly adapted to deposit a series of short strips or spots 2 of solder, illustrated in dotted lines in FIG. 4 and oriented along an axis X-X′, upon a lead frame 3. The strips 2 will be later used by reflow process to connect outside leads to an electronic package. The template 1 is constituted by a slab of material having a melting temperature substantially higher than melting point of the solder such as a gold alloy solders such Au/Sn solder, preferably, a high density graphite.

The bottom surface 4 of the template is machined to intimately match and rest upon the zone into which the areas wherein the solder is to be deposited are located; in this case, the flat top surface 5 of the lead frame. A series of cavities 6 cut into the bottom face 4 of the template are shaped and dimensioned to congruently fit over the areas to be occupied and delineated by the solder strip 2. The depths D of the cavities must be at least as great as the desired height of the solder strip 2. A series of sets 7 of channels or bores 8 are drilled from the upper surface 9 of the template toward the cavities 6. Each set 7 of bores terminates into a number of lower openings 10 regularly spaced-apart in the roof 11 of a cavity along a line substantially parallel to the axis X-X′ of the cavities.

It should be understood that if the limited area that will receive the solder is a small spot, the cavity may be circular and be fed by a single channel.

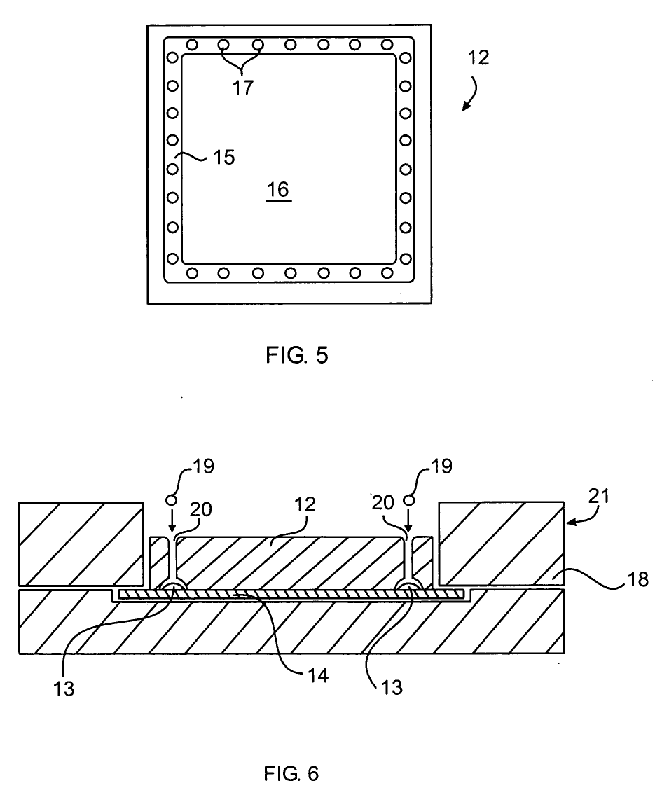

As illustrated in FIGS. 5 and 6, a quadrangular template 12 is specifically intended for use in depositing a continuous bead 13 of solder along a marginal, peripheral area of an electronic package lid 14 in accordance with the present embodiment. A cavity 15 matching the outline of the desired bead 13 is cut into the bottom surface 16 of the template 12. Bores 17 have their lower openings distributed at regularly spaced-apart locations along the roof of the cavity 15.

FIG. 6 illustrates the positioning of the template 12 over the package lid 14 within a special jig or fixture 18. A solder particle 19 of a defined volume shape such as a sphere and constituted by a metered volume of solder is inserted in the upper opening 20 of each bore.

The whole assembly 21 comprising the fixture 18, the package lid 14 and the loaded template 12 is then placed into an oven and exposed to a temperature sufficient to melt the solder under a controlled atmosphere. When melting, the solder from the particles flows into the cavities and deposits very accurately in the area limited by the overhead cavity 15. The solder is distributed evenly in a continuous strip to a thickness that depends upon the size and number of the solder particles 19.

After a cooling period, the template 12 is removed leaving a narrow bead of solder on the periphery of the lid 14 for future reflow attachment when the lid is installed upon an electronic package.

The particles 19 of solder are preferably manufactured according to dropping and blowing process well-known to people skilled in the art of lead pellet fabrication.

The size of the particles and the diameter of the bores are determined by first calculating the total volume of the soldered strip or spot, that is, the product of superficies of the targeted area times the desired height of the solder deposit. This total volume is then divided by the number of bores leading to the cavity capping that area.

In most electronic package assembly applications where the width of the soldered traces falls within the range of about 0.3 millimeters (12 mils) and about 0.7 millimeters (28 mils), the particles can be spheres having a diameter between about 0.35 millimeters (14 mils) and about 0.65 millimeters (26 mils) with spacing between the bores of approximately 1 millimeter (40 mils). It should be understood that the particles can be provided in shapes other than spheres, such as cylinders, quadrangularly sided shapes such as blocks, or other readily manufactured shapes having a defined volume.

### EXAMPLE

For the common Au/Sn solder, the electronic component and template assembly is preferably exposed to a temperature of approximately 360 degrees Celsius for thirty minutes in an oven hot zone under an atmosphere of 5% H2/95%N2 with a gas flow of 10 CFH. The assembly is then moved to a cool zone for 20 minutes under continuous gas flow to prevent oxide formation.

While the preferred embodiment of the invention has been described, modifications can be made and other embodiments may be devised without departing from the spirit of the invention and the scope of the appended claims.

What is claimed is:

1. A method for accurately depositing a volume of solder of a given melting point to a given height on a delineated area of given superficies on the face of an electronic component, said method comprising the steps of:
providing a slab of material having a bottom surface shaped and dimensioned for intimate contact with a zone of said face including said area, and a melting temperature substantially higher than said melting point;
drilling through said slab at least one bore substantially perpendicular to said bottom surface and having a lower opening in said bottom surface falling within said area when said bottom surface is in contact with said zone;
carving into said bottom surface and around said bottom opening, a cavity at least as deep as said height and shaped to be congruent with said delineated area;
intimately contacting said face with said slab's bottom surface;
inserting into said bore, a particle of said solder, said particle having a volume substantially equal to a product of said superficies times said height; and
exposing said component and slab to a temperature at least equal to said melting point; whereby said particle of solder melts, flows and deposits accurately over said delineated area.

2. The method of claim 1, wherein said delineated area is elongated about an axis;
said step of drilling comprises drilling a plurality of said bores leading to spaced-apart openings along a line parallel to said axis within said cavity; and
said step of inserting comprises inserting at least one of said particles in each of said bores, said particles having a cumulative volume equal to said product.

3. The method of claim 1, wherein said material comprises high density graphite.

4. The method of claim 3, wherein said solder comprise a gold alloy.

5. The method of claim 4, wherein said alloy is Au/Sn.

6. The method of claim 2, wherein said delineated area comprises an electronic package lead attachment area on a lead frame.

7. The method of claim 2, wherein said delineated area comprises a marginal, peripheral area on an electronic package lid.

8. A device for accurately depositing a volume of solder to a given height on a limited area on the face of an electronic component which comprises:
a slab of material having a top surface, and a bottom surface shaped and dimensioned for conformingly resting upon a zone of said face including said area;
said slab having at least one bore having a upper opening in said top surface and a lower opening in said bottom surface, said lower opening being positioned above said area when said bottom surface rests upon said zone; and
said slab further having a cavity in said bottom surface and around said bottom opening, said cavity having a depth greater than said height, and being shaped to congruently fit over said limited area.

9. The device of claim 8, which comprises a plurality of said bores having lower openings positioned at regularly spaced-apart locations along a line.

10. The device of claim 9, wherein said limited area comprises at least one lead connection spot on an electronic package lead frame.

11. The device of claim 9, wherein said limited area comprises a marginal, peripheral area on an electronic package lid.

12. The device of claim 9, which further comprises a small volume of solder inserted in each of said bores.

13. The device of claim 12, wherein said volume is obtained by dividing the amount of solder to be deposited by the number of bores.

14. The device of claim 13, wherein each of said volume consists of a particle of solder.

15. The device of claim 14, wherein said particle of solder has a shape selected from the group consisting of a sphere, a cylinder, and a quadranglarly sided shape.
